(19) United States
(12) Patent Application Publication
(10) Pub. No.: US 2017/0167668 A1
(43) Pub. Date: Jun. 15, 2017

(54) LENS UNIT, LED MODULE WITH THE LENS UNIT, AND LIGHT FIXTURE WITH THE LED MODULE

(71) Applicant: Panasonic Intellectual Property Management Co., Ltd., Osaka (JP)

(72) Inventors: Koji UENOYAMA, Kyoto (JP); Yoshimichi ENNO, Osaka (JP)

(21) Appl. No.: 15/374,019

(22) Filed: Dec. 9, 2016

(30) Foreign Application Priority Data
Dec. 10, 2015 (JP) 2015-241431

(51) Int. Cl. F21K 9/66; F21V 23/02; F21V 23/00; F21V 29/76; H01L 25/075; F21V 17/04; F21V 17/10; F21V 3/02; H01L 33/48; F21V 21/26; F21V 21/30

(52) U.S. Cl. CPC F21K 9/66; F21V 21/26; F21V 23/02; F21V 23/002; F21V 29/763; F21V 21/30; F21V 17/04; F21V 17/10; F21V 3/02; H01L 33/486; H01L 25/0753; F21V 3/0409

(57) ABSTRACT

A lens unit includes: lens cores configured to be provided one-to-one in front of LEDs with different luminous colors; and a main body that holds the lens cores. The lens cores is held by the main body so that respective distances of the lens cores from respective light-emitting surfaces of LED chips in the LEDs are equal to each other.

### CROSS REFERENCE TO RELATED APPLICATION

This application claims the benefit and priority of Japanese Patent Application No. 2015-241431, filed on Dec. 10, 2015, the entire content of which is incorporated herein by reference.

### TECHNICAL FIELD

The present disclosure relates to a lens unit, an LED module with the lens unit, and a light fixture with the LED module

### BACKGROUND ART

In recent years, LEDs (light emitting diodes) have been employed as a light source of a light fixture.

In this sort of light fixture, it is known that a light source includes an array of unit elements (unit light sources) arranged on a substrate (e.g., see Document 1 (JP 2011-204397 A)).

In Document 1, each of the unit elements has an LED structure in which a chip LED device is covered with a dome-shaped optical resin lens. According to Document 1, prescribed luminous intensity distribution can be obtained by arranging unit elements, including different kinds of optical resin lenses that are different in height, in a particular pattern. Document 1 is however silent about the configuration in which respective optical resin lenses, for different luminous colors of chip LED devices, are different in height.

Incidentally, when emitting color mixing light from different luminous colors of chip LED devices, light fixtures require radiating light with color irregularity (irregular color) thereof more reduced on a radiation surface. However, the configuration simply obtained from Document 1 is insufficient to radiate such light, and further improvement is required.

### SUMMARY

It is an object of the present disclosure to provide a lens unit, an LED module with the lens unit, and a light fixture with the LED module, capable of radiating light with color irregularity thereof more reduced on a radiation surface.

A lens unit according to an aspect of the present disclosure includes a plurality of lens cores and a main body. The plurality of lens cores is configured to be provided one-to-one in front of a plurality of LEDs with different luminous colors. The main body holds the plurality of lens cores. The plurality of lens cores is held by the main body so that respective distances of the plurality of lens cores from respective light-emitting surfaces of LED chips in the plurality of LEDs are equal to each other.

An LED module according to an aspect of the present disclosure includes a mounting substrate, a plurality of LEDs and a lens unit. The mounting substrate includes a mounting surface. The plurality of LEDs includes at least first and second LEDs that are mounted on the mounting surface and configured to radiate different luminous colors of light. The first and second LEDs respectively include first and second LED chips, each of which includes a luminous layer with a light-emitting surface. The light-emitting surfaces of the first and second LED chips have different first and second heights from the mounting surface, respectively. The lens unit includes a plurality of lens cores including at least first and second lens cores, and a main body holding the plurality of lens cores. The lens unit is provided to cover the mounting substrate with the first and second lens cores respectively disposed in front of the first and second LEDs. The first and second lens cores have first and second distances, respectively. The first and second distances are distances from the light-emitting surfaces of the first and second LEDs to the first and second lens cores, respectively. The first and second lens cores also have first and second intervals, respectively. The first and second intervals are intervals from the mounting surface to the first and second lens cores, respectively. A difference between the first and second distances is smaller than a difference between the first and second intervals.

A light fixture according to an aspect of the present disclosure includes the LED module, and a fixture body that holds the LED module.

The lens unit according to the aspect of the present disclosure is capable of radiating light with color irregularity thereof more reduced on a radiation surface.

The LED module according to the aspect of the present disclosure can have the configuration with the lens unit capable of radiating light with color irregularity thereof more reduced on a radiation surface.

The light fixture according to the aspect of the present disclosure can have the configuration with the LED module capable of radiating light with color irregularity thereof more reduced on a radiation surface.

### BRIEF DESCRIPTION OF THE DRAWINGS

The figures depict one or more implementations in accordance with the present teaching, by way of example only, not by way of limitation. In the figures, like reference numerals refer to the same or similar elements where:

FIG. 1 is a sectional view partially representing main parts of an LED module with a lens unit according to an embodiment;

FIG. 2 is a front view of the lens unit according to the embodiment;

FIG. 3 is a rear view of the lens unit according to the embodiment;

FIG. 4 is a perspective view representing a rear side of the lens unit according to the embodiment;

FIGS. 5A and 5B represent main parts of the LED module in the embodiment: FIG. 5A is a sectional view representing a positional relation between a first lens core and a first LED in the embodiment, and FIG. 5B is a sectional view representing a positional relation between a second lens core and a second LED in the embodiment;

FIG. 6 is an exploded perspective view representing the LED module in the embodiment;

FIG. 7 is a perspective view representing a front side of a light fixture with the LED module in the embodiment; and

FIG. 8 is a perspective view representing a rear side of the light fixture with the LED module in the embodiment.

### DETAILED DESCRIPTION

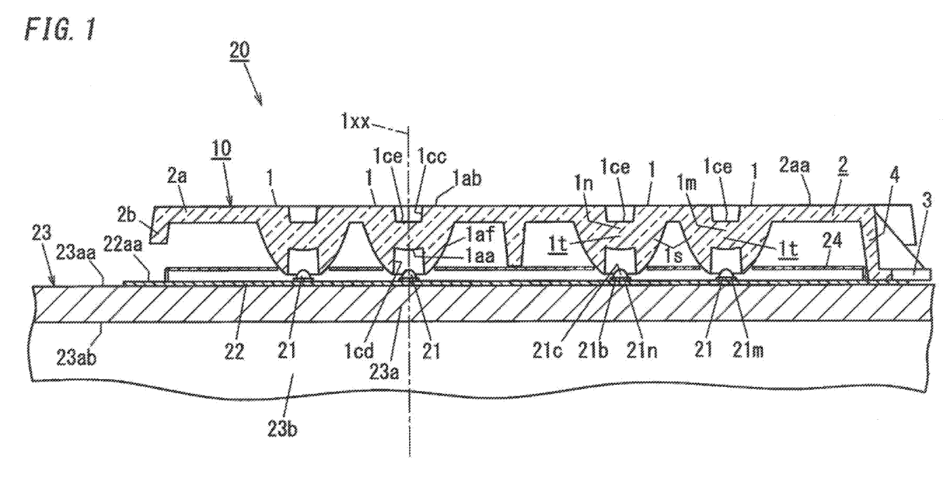

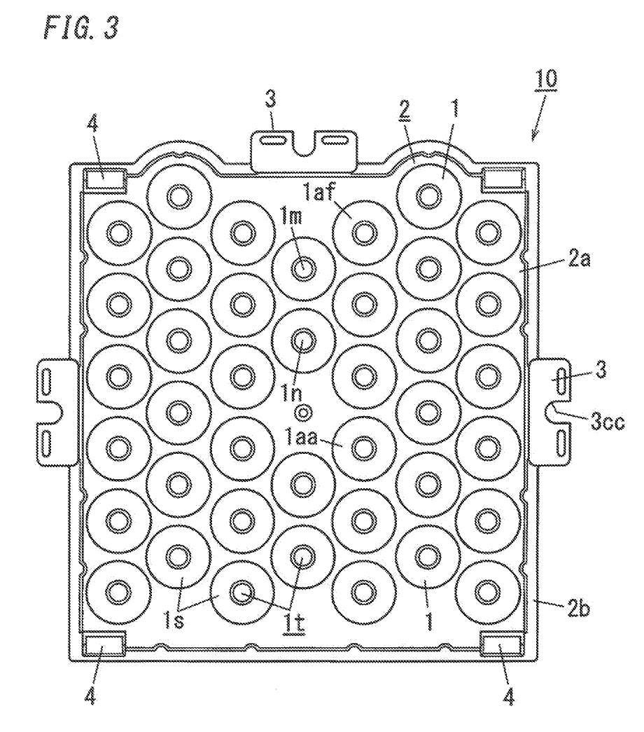

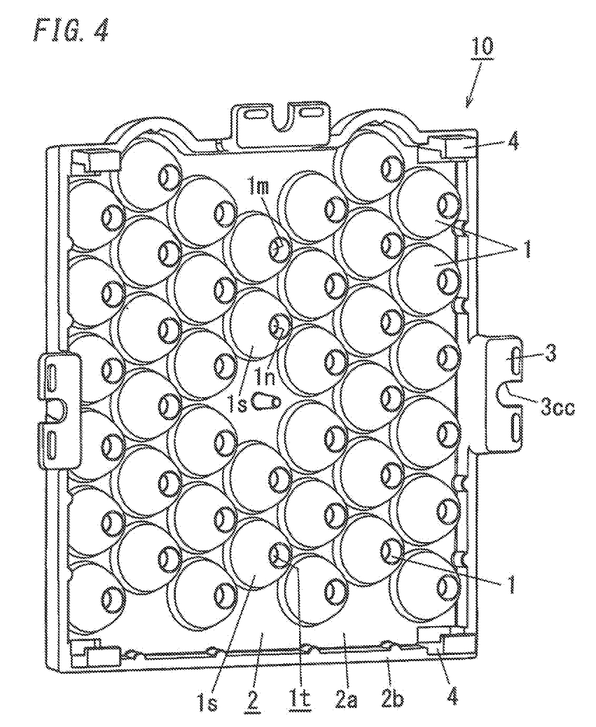

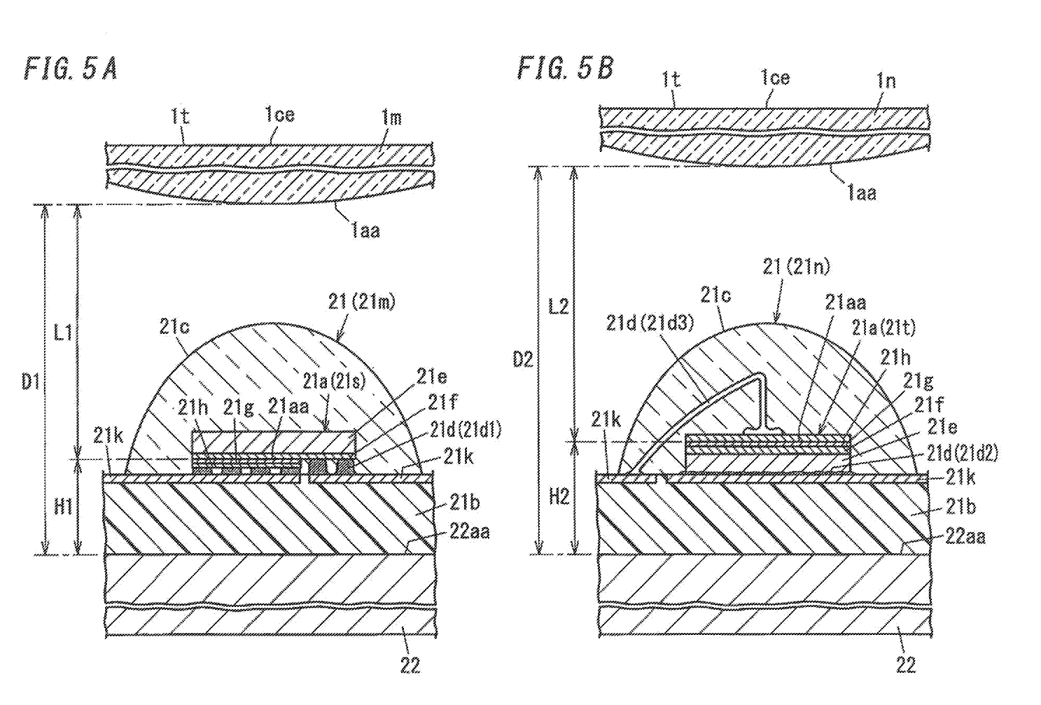

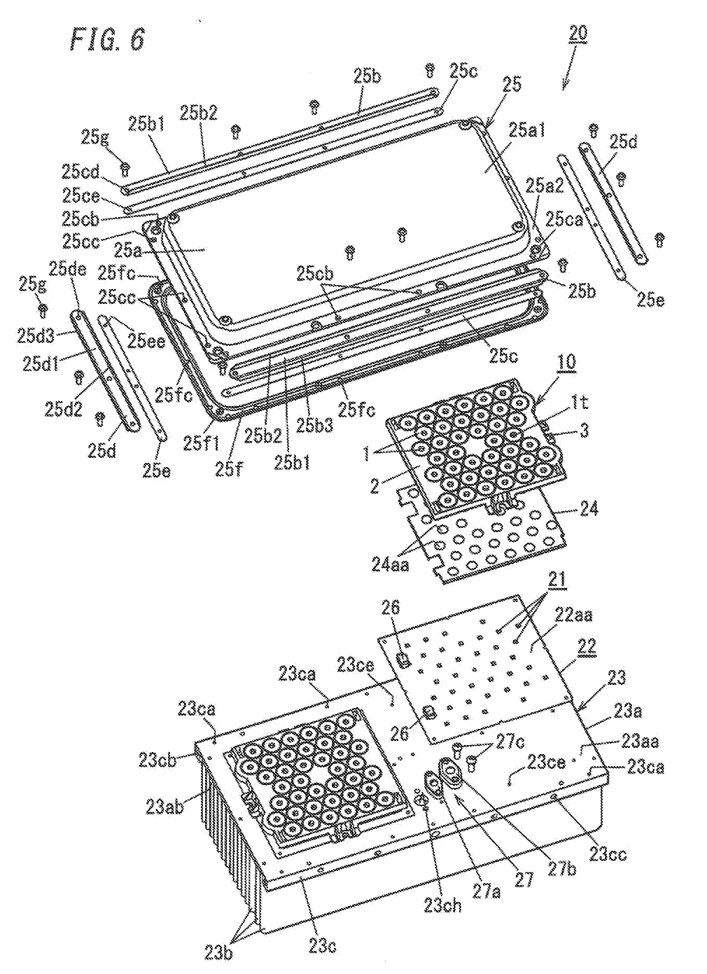

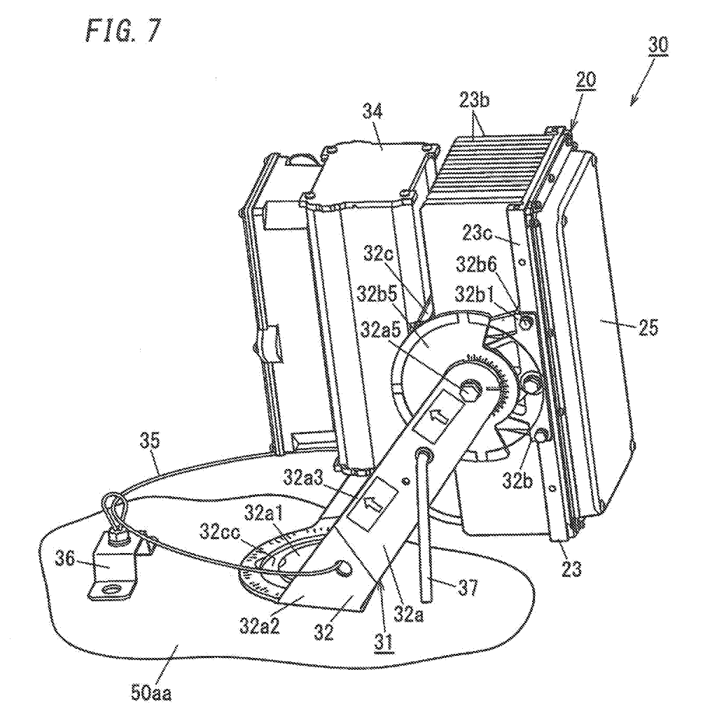

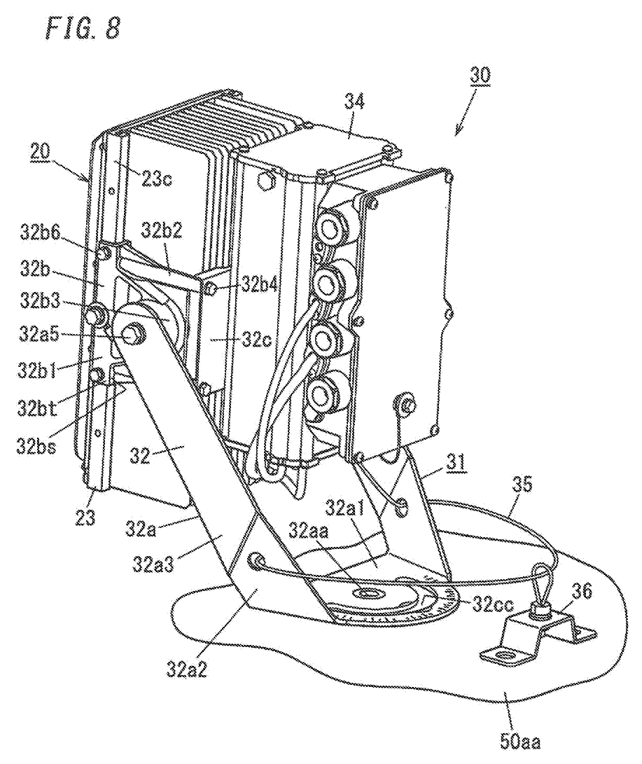

Hereinafter, a lens unit 10 according to the present embodiment will be explained with reference to FIG. 1 to FIGS. 5A and 5B, an LED module 20 will be explained with reference to FIG. 1, FIGS. 5A and 5B and FIG. 6, and a light fixture 30 will be explained with reference to FIG. 7 and FIG. 8. In the drawings, like kind elements are assigned identical reference numerals and redundant description will be omitted. Dimensions and positional relations of elements in the drawings may be exaggerated in order to clarify the explanation. In the explanation below, each element constituting the present embodiment may be one member which is composed of two or more elements, or be two or more members that function as one element.

As shown in FIGS. 1 and 6, the LED module 20 in the present embodiment includes a plurality of LEDs 21, a mounting substrate 22 and the lens unit 10. The plurality of LEDs 21 is mounted on a mounting surface 22aa of the mounting substrate 22. The lens unit 10 is provided to cover the mounting substrate 22. The plurality of LEDs 21 includes at least first and second LEDs 21m and 21n. The first and second LEDs 21m and 21n are configured to radiate different luminous colors of light.

As shown in FIG. 5A, the first LED 21m has a first LED chip 21s with a luminous layer 21g. As shown in FIG. 5B, the second LED 21n has a second LED chip 21t with a luminous layer 21g. The first and second LED chips 21s and 21t have different heights from the mounting surface 22aa to light-emitting surfaces 21aa of respective luminous layers 21g. In an example of FIG. 5A, a distance H1 represents the height from the mounting surface 22aa to the light-emitting surface 21aa of the luminous layer 21g in the first LED chip 21s. In an example of FIG. 5B, a distance H2 represents the height from the mounting surface 22aa to the light-emitting surface 21aa of the luminous layer 21g in the second LED chip 21t.

As shown in FIG. 1, the lens unit 10 includes a plurality of lens cores 1t, and a main body 2. The main body 2 holds the plurality of lens cores 1t. The plurality of lens cores it includes at least first and second lens cores 1m and 1n. The first lens core 1m is disposed at a position corresponding to the first LED 21m (in front of the first LED 21m). The second lens core 1n is disposed at a position corresponding to the second LED 21n (in front of the second LED 21n). That is, the plurality of lens cores it is provided to face the light-emitting surfaces 21aa of the plurality of LEDs 21, respectively. Referring again to FIGS. 5A and 5B, the first lens core 1m has a first distance L1 and a first interval D1, and the second lens core 1n has a second distance L2 and a second interval D2. The first distance L1 is a distance from the light-emitting surface 21aa of the first LED 21m to the first lens core 1m. The second distance L2 is a distance from the light-emitting surface 21aa of the second LED 21n to the second lens core 1n. The first interval D1 is an interval between the mounting surface 22aa and the first lens core 1m. The second interval D2 is an interval between the mounting surface 22aa and the second lens core 1n. In the present embodiment, a difference between the first and second distances L1 and L2 is smaller than a difference between the first and second intervals D1 and D2.

With the LED module 20 in the embodiment, the first and second lens cores 1m and 1n have the structure in which the difference between the first and second distances L1 and L2 is smaller than the difference between the first and second intervals D1 and D2, thereby making it possible to radiate light with color irregularity thereof more reduced on a radiation surface because such a small difference between the first and second distances L1 and L2 can provide similar optical properties to each LED 21 with respect to the radiation surface.

Hereinafter, the LED module 20 and the light fixture 30, including the lens unit 10 of the embodiment will be explained in more detail. The LED module 20 forms a light source of the light fixture 30. The light fixture 30 forms, for example a light projector for lighting up a building.

As shown in FIG. 6, in addition to the lens unit 10, the LEDs 21 and the mounting substrate 22, the LED module 20 includes a radiator (a heat dissipating member) 23, a light blocking sheet 24, a cover block 25 and a cable ground 27.

The lens unit 10 has translucency. As shown in FIGS. 1 to 4, in addition to the plurality of lens cores it and the main body 2, the lens unit 10 includes a plurality of lens frames is, fixed pieces 3 and support pieces 4.

Each of the plurality of lens cores it is held by the main body 2 through a corresponding lens frame 1s. Each lens core it and a corresponding lens frame 1s constitute a lens body 1. The lens body 1 is configured so that light from a corresponding LED 21 has prescribed luminous intensity distribution characteristics. For example, the lens body 1 is in the shape of a paraboloid of revolution (a solid of revolution) that protrudes toward a corresponding LED 21. The lens body 1 has a first recess 1cc. The first recess 1cc is set further back than an outgoing surface lab in an outer flat surface 2aa of the main body 2 along the imaginary axis of revolution 1xx of the paraboloid of revolution. The first recess 1cc has an open cylindrical concave surface, an axis of which is the same as the axis of revolution 1xx. The lens body 1 also has a second recess 1cd. The second recess 1cd is formed on a vertex side of the paraboloid of revolution so as to be set further back along the axis of revolution 1xx. In a section view along the axis of revolution 1xx, the lens core it forms an inner bottom of the first recess 1cc and has a convex shape that protrudes from an opposite side thereof from the first recess 1cc. In other words, the inner bottom of the first recess 1cc forms a light exit surface ice of the lens core it. An inner bottom of the second recess 1cd forms a light entrance surface 1aa of the lens core it. The lens core it forms a plano-convex lens between the light exit surface ice of the first recess 1cc and the light entrance surface 1aa of the convex shape. The lens frame 1s is disposed around the periphery of lens core it about the axis of revolution 1xx.

The lens body 1 is formed with the lens frame 1s and the lens core 1t that allow (part of) a corresponding LED 21 to be housed in the second recess 1cd. The lens core it is configured so that the light entrance surface 1aa receives light radiated from the LED 21 to radiate the light from the light exit surface ice. The lens body 1 is configured so that a paraboloid 1af of the lens frame 1s reflects part of light, which is radiated from the LED 21 and enters the lens core it, to be radiated from a side of the outgoing surface lab.

In the present embodiment, the lens unit 10 includes a plurality of lens bodies 1 that are formed so that respective first recesses 1cc thereof corresponding to different luminous colors of LEDs 21 have different depths along the axis of revolution 1xx. The plurality of lens bodies 1 are formed so that respective distances from the outgoing surface lab to tip ends of respective paraboloid of revolution corresponding to different luminous colors of LEDs 21 along the axis of revolution 1xx are different from each other. The plurality of lens bodies 1 are formed so that the second recesses 1cd thereof corresponding to different luminous colors of LEDs 21 have different depths along the axis of revolution 1xx. In the plurality of lens bodies 1, lens bodies 1 with a shallower first recess 1cc have respective second recesses 1cd deeper than those of lens bodies 1 with a deeper first recess 1cc. Each lens core (plano-convex lens) it of the plurality of lens bodies 1 has a light entrance surface 1aa and a light exit surface ice along the axis of revolution 1xx, and a thickness (a thickness of the lens core it) therebetween. The thicknesses of the lens cores it are equal (substantially similar enough to constitute “equal”) to each other, which may however be different from each other as long as color irregularity on a radiation surface by respective light radiated from the LEDs 21 via the lens cores it in the LED module 20 is substantially imperceptible to a human. That is, in the lens unit 10 with the plurality of lens bodies 1, the plurality of lens cores it, the thicknesses of which are equal to each other, is arranged so that the first and second recesses 1cc, 1cd corresponding to different luminous colors of LEDs 21 have different depths. Desirably, each lens core it is formed so that a distance to the light entrance surface 1aa thereof from the light-emitting surface 21aa of a corresponding LED 21 is the same as that of each of the plurality of LEDs 21.

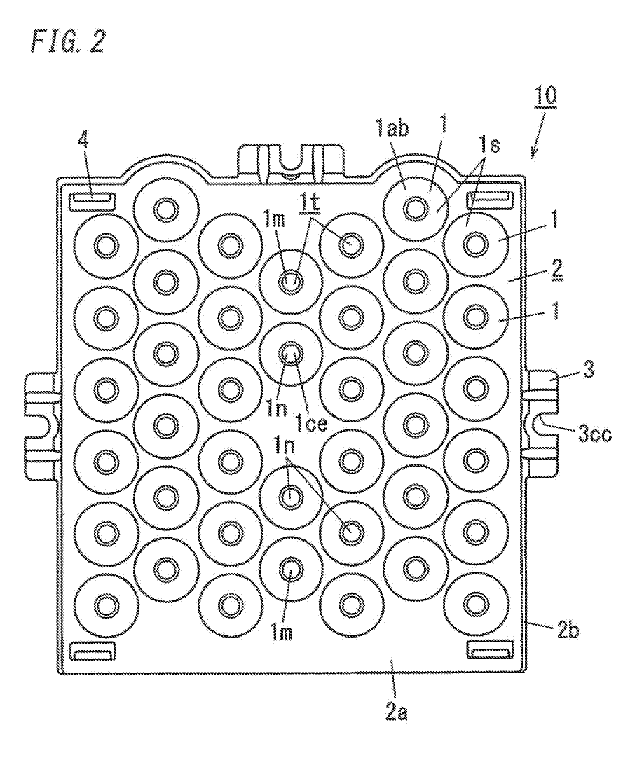

For example, the main body 2 includes a base plate 2a and a peripheral wall 2b. The base plate 2a is flat rectangular in outline. The peripheral wall 2b is provided along a peripheral edge of the base plate 2a. The peripheral wall 2b protrudes in a thickness direction of the base plate 2a. The base plate 2a is provided with the plurality of lens cores it in two-dimensional array with the plurality of lens cores it corresponding one-to-one to the plurality of LEDs 21 mounted on the mounting substrate 22. The main body 2 is provided with (a) fixed pieces 3 (in FIG. 2, three fixed pieces 3) that protrude from an edge of the peripheral wall 2b. The fixed pieces 3 are in the shape of an L in side view. As shown in FIG. 2, the fixed pieces 3 are provided one each at three sides of the rectangular base plate 2a in plan view. Preferably, one or more fixed pieces 3 are provided. In other words, the peripheral wall 2b is provided with the three fixed pieces 3 in plan view. Each fixed piece 3 is formed with a cut 3cc in a center thereof in plan view. The cut 3cc is elongated inwards and thereby the fixed piece 3 is in the shaped of a C. The support pieces 4 are respectively provided at four corners of the rectangular main body 2. The support pieces 4 have a function of forming a gap between the peripheral wall 2b and the mounting substrate 22 with the base plate 2a placed to cover the mounting substrate 22.

The lens unit 10 has a configuration in which the plurality of lens cores 1t, the plurality of lens frames 1s, the main body 2, the fixed pieces 3 and the support pieces 4 are formed integrally. Material of the lens unit 10 is, for example synthetic resin material such as acrylic resin. For example, the lens unit 10 may be formed by injection molding. In another example of the lens unit 10, the plurality of lens bodies 1 may be separated from the main body 2 and configured to be attached to the main body 2.

As shown in FIGS. 5A and 5B, each of the plurality of LEDs 21 includes an LED chip 21a, a base substance 21b, an encapsulation member 21c, and connection members (in each figure, two connection members) 21d. FIG. 5A illustrates the structure of the first LED 21m, and FIG. 5B illustrates the structure of the second LED 21n. Hereinafter, the common structure to the first and second LEDs 21m, 21n will be first explained.

The LED chip 21a includes a substrate 21e, a first conductivity type semiconductor layer (hereinafter simply called a “semiconductor layer”) 21f, the luminous layer 21g, and a second conductivity type semiconductor layer (“semiconductor layer”) 21h. The semiconductor layer 21f is provided on the substrate 21e. For example, the semiconductor layer 21f is made of n-type semiconductor material. The luminous layer 21g is provided on an opposite side of the semiconductor layer 21f from the substrate 21e. The semiconductor layer 21h is provided on an opposite side of the luminous layer 21g from the semiconductor layer 21f. For example, the semiconductor layer 21h is made of p-type semiconductor material.

For example, the LED chip 21a is a semiconductor light emitting device, and manufactured by epitaxial growth and thermal diffusion of semiconductor. Examples of the semiconductor material of the luminous layer 21g include InGaN, AlInGaN, AlInGaP, GaAsP and the like.

For example, the base substance 21b is a flat rectangular substrate. The LED chip 21a is mounted on the base substance 21b. Lead terminals 21k are provided on a surface of the base substance 21b. In each of FIGS. 5A and 5B, two lead terminals 21k are provided on the surface of the base substance 21b. The lead terminals 21k are configured to feed power to the LED chip 21a. The base substance 21b is, for example a ceramic substrate. The base substance 21b is not limited to the ceramic substrate, but examples thereof may further include a resin substrate and the like.

The encapsulation member 21c is provided on the base substance 21b so as to cover and seal the LED chip 21a. The encapsulation member 21c forms the convex lens. For example, the material of the encapsulation member 21c is silicone resin. The material of the encapsulation member 21c is not limited to the silicone resin, but examples thereof may further include epoxy resin, acrylic resin and glass. Each LED 21 is provided with the convex lens, thereby capable of enhancing light-extraction efficiency of the LED chip 21a. Note while the convex lens is preferably provided for each LED 21, it is not absolutely necessary. In the embodiment, each convex lens functions as a primary lens that allows the light from the LED chip 21a to directly strike, while each lens body 1 of the lens unit 10 functions as a secondary lens for controlling distribution of luminous intensity of light from the convex lens of a corresponding LED 21. The external shapes of the convex lenses of the first and second LEDs 21m, 21n in the plurality of LEDs 21 are equal to each other.

In the common structure, the connection members 21d electrically connect both electrodes of the LED chip 21a with the lead terminals 21k provided on the base substance 21b. Examples of the connection member 21d include (a) metal bumps 21d1, an electrical conductive resin 21d2, a metal wire 21d3, and the like. The metal bumps 21d1 may be solder bumps or ball bumps. The electrical conductive resin 21d2 may be Ag paste or the like. The metal wire 21d3 may be a gold wire, an aluminum wire or the like.

The first LED 21m is mounted on and electrically connected with the base substance 21b via the metal bumps 21d1. In the first LED 21m shown in FIG. 5A, the semiconductor layer 21f of the LED chip 21a is electrically connected to one of the two lead terminals 21k provided on the base substance 21b via metal bumps 21d1. In addition, the semiconductor layer 21h of the LED chip 21a is electrically connected to the other of the two lead terminals 21k provided on the base substance 21b via metal bumps 21d1. In the first LED 21m, the substrate 21e of the LED chip 21a is formed of an optically transparent (electrical) insulator.

In the second LED 21n shown in FIG. 5B, the electrical conductive substrate 21e of the LED chip 21a is electrically connected to one of the two lead terminals 21k provided on the base substance 21b via the electrical conductive resin 21d2. In addition, the semiconductor layer 21h of the LED chip 21a is electrically connected to the other of the two lead terminals 21k provided on the base substance 21b via the metal wire 21d3.

As shown in the example of FIG. 6, the mounting substrate 22 is a flat rectangular substrate. The mounting substrate 22 is not limited to such a rectangular substrate, but examples thereof may further include a circular substrate and an elliptical substrate. A two-dimensional array of LEDs 21 is disposed on the mounting surface 22aa of the mounting substrate 22. Receptacle connectors 26 are mounted on the mounting surface 22aa of the mounting substrate 22. The receptacle connectors 26 are electrically connected with the plurality of LEDs 21 via a conductive pattern formed on the mounting substrate 22. For example, the mounting substrate 22 is a metal-based printed circuit board. The mounting substrate 22 is not limited to the metal-based printed circuit board, but may be a ceramic substrate, a glass epoxy resin substrate or the like.

As shown in FIGS. 1, 6, 7 and 8, the radiator 23 includes a base 23a, radiation fins 23b, and side edges 23c. The base 23a has an elongated flat rectangular outline. The base 23a is provided with first screw holes 23ce in a first surface 23aa on which the mounting substrate 22 is mounted. Each first screw hole 23ce is formed with an internal thread. The base 23a is provided with a first insertion hole 23ch pierced in the base 23a in a thickness direction thereof. The first insertion hole 23ch is in a center, in a length direction, of the base 23a and at one side in a width direction of the base 23a. The cable ground 27 is attached to a side of the first insertion hole 23ch of the base 23a. A power feed cable for feeding power to the plurality of LEDs 21 is inserted into the base 23a through the cable ground 27.

The radiation fins 23b protrude from a second surface 23ab that is an opposite surface of the base 23a from the first surface 23aa. For example, each radiation fin 23b is a flat rectangular fin. The radiation fins 23b are arranged at prescribed intervals on the base 23a. The radiation fins 23b may be arranged at regular or irregular intervals on the base 23a. The radiation fins 23b can efficiently radiate heat generated by the plurality of LEDs 21 from a side of the second surface 23ab of the base 23a on which the mounting substrate 22 is mounted.

For example, each side edge 23c is in the shape of a rectangular solid. Each side edge 23c is provided along a long side of the rectangular base 23a in plan view. The base 23a is provided with the two side edges 23c. The two side edges 23c are disposed opposite to each other via the base 23a. Each side edge 23c has a dimension larger than that of the base 23a in the thickness direction of the base 23a. Each side edge 23c includes first connectors 23ca along the thickness direction of the base 23a, which are connected with the cover block 25. Each first connector 23ca is formed of a second screw hole. The second screw hole is formed with an internal thread. A plurality of first connectors 23ca is arranged along a length direction of each side edge 23c.

Preferably, each side edge 23c includes second connectors 23cb, along the length direction thereof perpendicular to the thickness direction of the base 23a, which are configured to be connected with another member. Each second connector 23cb is formed of a third screw hole. The third screw hole is formed with an internal thread. The second connectors 23cb are provided one each in both end faces, in the length direction, of each side edge 23c. Each side edge 23c is provided with third connectors 23cc along a direction perpendicular to both the thickness direction of the base 23a and the length direction of the side edges 23c. The third connectors 23cc allow the side edges 23c to be connected with one or more other member. Each third connector 23cc is formed of a fourth screw hole piercing a corresponding side edge 23c. The fourth screw hole is formed with an internal thread. Along the length direction of each side edge 23c, corresponding third connectors 23cc are disposed at prescribed intervals.

The radiator 23 is made of metal material so that the base 23a, the radiation fins 23b and the side edges 23c are formed integrally. For example, the material of the radiator 23 is metal material with superior thermal conductivity. The examples of the metal material with superior thermal conductivity include aluminum alloy and copper alloy.

For example, the light blocking sheet 24 is a flat rectangular sheet. The light blocking sheet 24 is slightly smaller than the main body 2 and configured to be housed in the lens unit 10. The light blocking sheet 24 is provided with a plurality of holes 24aa piercing the light blocking sheet 24 in a thickness direction thereof. Each of the plurality of holes 24aa allows the lens frame 1s of a corresponding lens body 1 of the lens unit 10 to be inserted into. The light blocking sheet 24 can absorb light leaking out from each paraboloid 1af of the lens frames is, thereby suppressing the occurrence of stripe radiation to a side of a radiation surface by luminous intensity distribution that is out of control at each lens core it. The light blocking sheet 24 is made from resin material containing carbon. Since the resin material contains the carbon, the light blocking sheet 24 is colored with black.

As shown in FIG. 6, the cover block 25 includes a cover 25a, a pair of first pressing plates 25b, a pair of first spacers 25c, a pair of second pressing plates 25d, a pair of second spacers 25e, and a seal member 25f. The cover 25a has a cover body 25a1 and a flange 25a2. For example, the cover body 25a1 is a rectangular or square case with a top base (in the example of FIG. 6, the rectangular case). For example, the flange 25a2 is an annular rectangular flange. The flange 25a2 protrudes sideways from a periphery of the cover body 25a1. The flange 25a2 is provided, in each corner thereof, with a circular fitting hole 25ca. A plurality of second insertion holes 25cb is provided in each long side of the flange 25a2 at prescribed intervals along a length direction thereof. A plurality of third insertion holes 25cc is provided in each short side of the flange 25a2 at prescribed intervals along a width direction thereof. FIG. 6 illustrates three third insertion holes 25cc in each short side and four second insertion holes 25cb in each long side. The cover body 25a1 and the flange 25a2 are formed integrally. The cover 25a has translucency. For example, the material of the cover 25a is synthetic resin material such as polycarbonate resin.

Each of the pair of first pressing plates 25b has an elongated shape and is slightly shorter than each long side of the flange 25a2. Each first pressing plate 25b has a first main piece 25b1, a first side piece 25b2 and a first end piece 25b3. For example, the first main piece 25b1 is in the shape of an elongated plate. The first main piece 25b1 is provided with fourth insertion holes 25cd that are pierced along a thickness direction of the first main piece 25b1 in both ends in a length direction and a center side thereof. The first side piece 25b2 protrudes from one of long sides of the first main piece 25b1 in a direction perpendicular thereto. The first end piece 25b3 protrudes from the other of the long sides of the first main piece 25b1 in the direction perpendicular thereto. The first side piece 25b2 and the first end piece 25b3 are disposed opposite to each other via the first main piece 25b1. Each first pressing plate 25b has a configuration in which the first main piece 25b1, the first side piece 25b2, and the first end piece 25b3 are formed integrally. The first pressing plate 25b is formed by punching and bending of a metal plate. For example, material of each first pressing plate 25b is a metal material such as stainless steel.

For example, each of the pair of first spacers 25c is in the shape of an elongated plate. Each first spacer 25c is slightly smaller than each first main piece 25b1 of the first pressing plates 25b. Each first spacer 25c is sandwiched between the first main piece 25b1 and the flange 25a2. Each first spacer 25c has first through-holes 25ce pierced in the first spacer 25c in a thickness direction thereof. Each first spacer 25c is provided with the first through-holes 25ce on respective positions corresponding to the fourth insertion holes 25cd of each first pressing plate 25b.

Each of the pair of second pressing plates 25d has an elongated shape and is slightly shorter than each short side of the flange 25a2. Each second pressing plate 25d has a second main piece 25d1, a second side piece d2 and a second end piece 25d3. For example, the second main piece 25d1 is in the shape of an elongated plate. The second main piece 25d1 is provided with fifth insertion holes 25de. The second side piece 25d2 protrudes from one of long sides of the second main piece 25d1 in a direction perpendicular thereto. The second end piece 25d3 protrudes from the other of the long sides of the second main piece 25d1 in the direction perpendicular thereto. The second side piece 25d2 and the second end piece 25d3 are disposed opposite to each other via the second main piece 25d1. Each second pressing plate 25d has a configuration in which the second main piece 25d1, the second side piece 25d2, and the second end piece 25d3 are formed integrally. The second pressing plate 25d is formed by punching and bending of a metal plate. For example, material of each second pressing plate 25d is a metal material such as stainless steel.

For example, each of the pair of second spacers 25e is in the shape of an elongated plate. Each second spacer 25e is slightly smaller than each second main piece 25d1 of the second pressing plates 25d. Each second spacer 25e is sandwiched between the second main piece 25d1 and the flange 25a2. Each second spacer 25e has second through-holes 25ee pierced in the second spacer 25e in a thickness direction thereof. Each second spacer 25e is provided with the second through-holes 25ee on respective positions corresponding to the fifth insertion holes 25de of each second pressing plate 25d.

For example, the seal member 25f is the shape of a rectangular frame. The seal member 25f has a similar size to the flange 25a2 of the cover 25. The seal member 25f is provided with a nib 25f1 on each corner thereof. The nibs 25f1 are fitted in the fitting holes 25ca of the cover 25a. The seal member 25f further includes sixth insertion holes 25fc pierced in the seal member 25f in a thickness direction thereof. Two or more sixth insertion holes 25fc are provided in each side of the seal member 25f along the side. For example, the seal member 25f is made of silicone resin.

The cable ground 27 includes a cable ground body 27a, a cap 27b and mounting screws 27c. The cap 27b is formed to cover the cable ground body 27a. The cable ground body 27a and the cap 27b are fixed to the base 23a with the mounting screws 27c. The cable ground 27 is configured to fasten a power feed cable inserted therein.

Hereinafter, a principle of light radiation with color irregularity more reduced on a radiation surface by the LED module 20 in the embodiment will be explained.

The LED module 20 of the embodiment includes, as the plurality of LEDs 21, red LEDs for radiating red light, green LEDs for radiating green light and blue LEDs for radiating blue light. The LED module 20 can radiate white light by mixing the red light from the red LEDs, the green light from the green LEDs and the blue light from the blue LEDs.

The LED chips 21a of the plurality of LEDs 21 are formed with respective luminous layer 21g by semiconductor material with bandgap corresponding to respective light energy to be radiated. The material of each luminous layer 21g of the red LEDs is, for example AlInGaP in order to emit red light with a peak emission wavelength of 620 nm. The material of each luminous layer 21g of the green LEDs is, for example InGaN in order to emit green light with a peak emission wavelength of 525 nm. The material of each luminous layer 21g of the blue LEDs is, for example InGaN containing an amount of 1n smaller than that of each luminous layer 21g of the green LEDs in order to emit blue light with a peak emission wavelength of 475 nm.

Each LED chip 21a is formed by a metal organic chemical vapor deposition method (a MOCVD method) in general. In this case, if the plurality of LEDs 21 includes different kinds of LED chips 21a, luminous layers 21g of which are made of different semiconductor material, respective layered structures of substrate 21e and semiconductor in the different kinds of LED chips 21a and the like differ from each other. The light-emitting surfaces 21aa of the different kinds of LED chips 21a may have different positions in each thickness direction thereof owing to different semiconductor material of the luminous layers 21g. Here, in each LED chip 21a, a surface side of the luminous layer 21g that faces a corresponding lens core 1t and radiates light towards the corresponding lens core 1t is called the light-emitting surfaces 21aa.

In the example of FIG. 5A, the material of each luminous layer 21g of blue LED chips and green LED chips is InGaN, and each of the blue LED chips and the green LED chips has the structure of the first LED 21m. In the example of FIG. 5B, the material of each luminous layer 21g of red LED chips is AlInGaP, and each red LED chip has the structure of the second LED 21n.

The plurality of LEDs 21 is employed for various applications, and therefore may be provided with a convex lens for efficient external radiation of light from the respective LED chips 21a. Each convex lens often has a similar external shape regardless of respective luminous colors of LED chips 21a. In the plurality of LEDs 21, different luminous colors of LED chips 21a cause different luminous intensity distribution characteristics with respect to the radiated light. In the LED module 20, a distance H2 is longer than a distance H1, where the distance H2 is a distance from the mounting surface 22aa of the mounting substrate 22 to a light-emitting surface 21aa of each red LED, and the distance H1 is a distance from the mounting surface 22aa of the mounting substrate 22 to a light-emitting surface 21aa of each green LED or each blue LED.

An LED module of a comparison example to be compared with the embodiment has the same distance from a mounting surface to each lens core thereof even when mixed color light is obtained from red LEDs, green LEDs and blue LEDs. Accordingly, the LED module of the comparison example may have color irregularity in the mixed color light on a radiation surface owing to different positions of light-emitting surfaces in the red LEDs, the green LEDs and the blue LEDs.

In the example of FIGS. 5A and 5B, different luminous colors of LEDs 21 in the lens unit 10 have different heights from respective light-emitting surfaces 21aa to respective lens cores 1t. In the lens unit 10 of the embodiment, each first interval D1 and each second interval D2 are different from each other. In addition, a difference between each first distance L1 and each second distance L2 (an absolute value thereof) is smaller than a difference between each first interval D1 and each second interval D2 (an absolute value thereof). In this case, a difference between each first distance L1 and each second distance L2 becomes small. In the lens unit 10 of the embodiment, it is preferable that each first distance L1 and each second distance L2 be equal to each other.

In other words, the lens unit 10 of the embodiment includes the plurality of lens cores it and the main body 2 as shown in FIGS. 1 to 4. The plurality of lens cores it is configured to be provided one-to-one in front of the plurality of LEDs 21 with different luminous colors. In the embodiment, the plurality of LEDs 21 includes different luminous colors of LED chips 21a. The main body 2 holds the plurality of lens cores 1t. The plurality of lens cores it is held by the main body 2 so that respective distances of the plurality of lens cores it from respective light-emitting surfaces 21aa of the LED chips 21a in the plurality of LEDs 21 are equal to each other.

With the lens unit 10 of the embodiment, since the plurality of lens cores it is held by the main body 2 so that the respective distances of the plurality of lens cores it from the respective light-emitting surfaces 21aa of the LED chips 21a in the plurality of LEDs 21 are equal to each other, it is possible to radiate light with color irregularity thereof more reduced on a radiation surface.

Assembly process of the LED module 20 is now explained.

In the assembly process of the LED module 20, the mounting substrate 22 on which the plurality of LEDs 21 is mounted in advance is mounted on the first surface 23aa of the base 23a in the radiator 23. The power feed cable provided with a plug connector at a tip thereof is inserted into the first insertion hole 23ch of the base 23a via the cable ground 27. The mounting substrate 22 is covered with the lens unit 10 via the light blocking sheet 24. In the LED module 20, the plurality of LEDs 21 is arranged so that the plurality of LEDs 21 corresponds one-to-one to the plurality of lens cores it of the lens unit 10.

The plug connector provided at the tip of the power feed cable inserted into the cable ground 27 is connected to the receptacle connectors 26. The support pieces 4 of the lens unit 10 are put on the first surface 23aa of the radiator 23, and the power feed cable is wired outside the lens unit 10 via the gap between the peripheral wall 2b and the mounting substrate 22. The fixed pieces 3 of the lens unit 10 are fixed to the base 23a with screws. In the assembly process of the LED module 20, the torque for fastening the screws is set such that no distortion by screw-fixing of the fixed pieces 3 occurs in the lens unit 10.

The cover block 25 is then attached to the base 23a. In the cover block 25, the seal member 25f is attached to the cover 25a with the nibs 25f1 fitted in the fitting holes 25ca. The cover 25a attached with the seal member 25f is arranged on a side of the first surface 23aa of the radiator 23 to cover the lens unit 10. The pair of first pressing plates 25b is stacked on the flange 25a2 of the cover 25 via the pair of first spacers 25c. The first pressing plates 25b, the first spacers 25c and the cover 25a are arranged so that the fourth insertion holes 25cd of the first pressing plates 25b, the first through-holes 25ce of the first spacers 25c, and the second insertion holes 25cb of the cover 25a are aligned with each other. In the cover block 25, second screws 25g are respectively inserted into the fourth insertion holes 25cd of the first pressing plates 25b, the first through-holes 25ce of the first spacers 25c, the second insertion holes 25cb of the cover 25a, and the sixth insertion holes 25fc of the seal member 25f.

The pair of second pressing plates 25d is stacked on the flange 25a2 of the cover 25a via the pair of second spacers 25e. The second pressing plates 25d, the second spacers 25e and the cover 25a are arranged so that the fifth insertion holes 25de of the second pressing plates 25d, the second through-holes 25ee of the second spacers 25e and the third insertion holes 25cc of the cover 25a are aligned with each other.

In the cover block 25, second screws 25g are respectively inserted into the fifth insertion holes 25de of the second pressing plates 25d, the second through-holes 25ee of the second spacers 25e, the third insertion holes 25cc of the cover 25a, and the sixth insertion holes 25fc of the seal member 25f. The second screws 25g are respectively screwed into the first connectors 23ca of the base 23a. The cover block 25 is fixed to the radiator 23 with the second screws 25g.

Hereinafter, the light fixture 30 of the embodiment will be explained with reference to FIGS. 7 and 8.

Note that in another embodiment, the light fixture 30 may include the LED module 20 and the fixture body 31, and the fixture body 31 may be configured to hold the LED module 20.

The light fixture 30 includes one LED module 20. The fixture body 31 includes a holder 32, a wiring box 34, a wire 35 and a wire holder 36. The holder 32 includes an arm member 32a, a pair of arm attaching members 32b and a coupling member 32c. The arm member 32a is configured to hold the LED module 20 via the pair of arm attaching members 32b.

The arm member 32a includes a fix plate 32a1, a pair of stand pieces 32a2, and a pair of support pieces 32a3. The arm member 32a is configured to hold the LED module 20 at a prescribed angle to an installation surface 50aa. For example, the fix plate 32a1 is in the shape of a flat plate. The fix plate 32a1 is fixed on the installation surface 50aa. As shown in FIG. 8, a fix hole 32aa is formed in a center of the fix plate 32a1. The fix hole 32aa is pierced in the fix plate 32a1 in a thickness direction thereof. The fix hole 32aa is shaped into a circle, for example. The fix plate 32a1 is provided with an elongated hole 32cc which is in the shape of a semicircular arc, and a center of which corresponds to the fix hole 32aa. The elongated hole 32cc is pierced in the fix plate 32a1 in the thickness direction. The fix plate 32a1 is fixed to a base of a projector or the like having the installation surface 50aa with a second bolt inserted into the fix hole 32aa and a third bolt inserted into the elongated hole 32cc. The stand pieces 32a2 are extended from both ends of the fix plate 32a1. Two stand pieces 32a2 are disposed opposite to each other via the fix plate 32a1. The support pieces 32a3 are further extended from tips of the stand pieces 32a2.

The arm member 32a has a configuration in which the fix plate 32a1, the pair of stand pieces 32a2, and the pair of support pieces 32a3 are formed integrally. Material of the arm member 32a is, for example metal material such as stainless steel. The arm member 32a is formed by punching and bending of a metal plate. The arm member 32a is configured so that loosening the third bolt inserted into the elongated hole 32cc of the fix plate 32a1 allows the orientation of the LED module 20 held by the arm member 32a to vary in a horizontal direction.

Each of the pair of arm attaching members 32b includes a fix member 32b1, a pair of attaching members 32b2, and a bearing member 32b3. The fix member 32b1 has a bottom wall 32bs and a pair of side walls 32bt. For example, the bottom wall 32bs is flat rectangular. The pair of side walls 32bt protrudes from both long sides of the bottom wall 32bs in a thickness direction of the bottom wall 32bs. For example, each side wall 32bt is in the shape of a flat rectangular plate. Each fix member 32b1 is shaped into a square gutter by the bottom wall 32bs and the pair of side walls 32bt. Each fix member 32b1 is formed so as to allow a side edge 23c of the LED module 20 to be fitted in. The pair of arm attaching members 32b is attached to the radiator 23 with the side edges 23c of the radiator 23 fitted in the fix members 32b1.

Each fix member 31b1 is provided with the pair of attaching members 32b2. For example, each attaching member 32b2 is in the shape of a truncated cone. Each attaching member 32b2 protrudes along the thickness direction of the bottom wall 32bs. Each attaching member 32b2 is formed with an internal thread in an end face thereof. One of the pair of arm attaching members 32b is provided with a dial plate 32b5. For example, the dial plate 32b5 is a flat plate in the shape of a sector. A scale is marked on the dial plate 32b5 in order to represent an angle of the LED module 20 to the installation surface 50aa. The dial plate 32b5 is joined to an end face of the bearing member 32b3 in the one of the pair of arm attaching members 32b.

Each bearing member 32b3 is in the shape of a cylinder. Each bearing member 32b3 is disposed between a corresponding pair of attaching members 32b2. Each bearing member 32b3 has a configuration in which the pair of attaching members 32b2 and the fix member 32b1 is joined to each other.

For example, the coupling member 32c is in the shape of an elongated plate. The coupling member 32c is attached to the pair of attaching members 32b2 with first bolts 32b4. The coupling member 32c is configured to hold the wiring box 34. The material of the coupling member 32c is, for example metal material such as stainless steel.

Each arm attaching member 32b has a configuration in which the fix member 32b1, the pair of attaching members 32b2 and the bearing member 32b3 are formed integrally. The fix member 32b1, the pair of attaching members 32b2 and the bearing member 32b3 are formed of an aluminum die casting.

For example, the wiring box 34 is in the shape of a rectangular box. A relay terminal block is housed in the wiling box 34. The wiring box 34 is configured so that the power feed cable of the LED module 20 and a power cable from an outside are connected via the terminal block. The power cable is connected with a power supply device installed outside the wiring box 34. In the light fixture 30, electric power is supplied from the power supply device to the LED module 20 via the terminal block of the wiring box 34. The light fixture 30 is not limited to the configuration in which the power supply device is installed outside the wiring box 34, but may be a configuration in which the power supply device is housed in the wiring box 34. The material of the wiring box 34 is, for example metal material such as stainless steel.

In the light fixture 30, fourth bolts 32a5 inserted into the pair of support pieces 32a3 are individually screwed into the bearing members 32b3 of the pair of arm attaching members 32b. The fourth bolts 32a5 are fixed to the bearing members 32b3, and thereby the light fixture 30 can pivotably hold the LED module 20 through the holders 32. Since one of the pair of arm attaching members 32b is provided with the dial plate 32b5, the light fixture 30 can display an angle of the LED module 20 to the installation surface 50aa around the fourth bolts 32a5. The light fixture 30 is configured to rotate the LED module 20 at a desired angle to the installation surface 50aa according to rotation of a lever 37 shown in FIG. 7.

In the embodiment, in case the light fixture 30 is installed on the installation surface 50aa of the base of the projector, both ends of the wire 35 are fixed to the pair of arm attaching members 32b with screws as shown in FIGS. 7 and 8. The wire 35 is supported by the wire holder 36 fixed to the installation surface 50aa. With the light fixture 30, even if the arm member 32a come off the installation surface 50aa, the wire 35 supports the arm members 32a, thereby preventing the light fixture 30 from falling.

Hereinafter, an assembly process of the light fixture 30 in the embodiment will be briefly explained.

In the assembly process of the light fixture 30, the side edges 23c of the radiator 23 in the LED module 20 are fitted in the fix members 32b1 of the pair of arm attaching members 32b. The side edges 23c of the radiator 23 are fixed to the fix members 32b1. In the light fixture 30, fifth bolts 32b6 are individually screwed into the third connectors 23cc of the side edges 23c via the pair of side walls 32bt of the fix member 32b1.

The coupling member 32c is then fixed to the pair of attaching members 32b2 of each arm attaching member 32b with the first bolts 32b4. The wiring box 34 is then attached to the coupling member 32c. In the assembly of the light fixture 30, after the wiring box 34 is attached to the coupling member 32c, the coupling member 32c may be attached to the pair of attaching members 32b2 of each arm attaching member 32b. After the wiring box 34 is attached to the coupling member 32c, the power cable and the power feed cable are connected. Finally in the assembly process of the light fixture 30, the fourth bolts 32a5 inserted into the pair of support pieces 32a3 are screwed into fifth screw holes in the bearing members 32b3 of the pair of arm attaching members 32b. As a result, the arm attaching members 32b are attached to the arm members 32a.

### Aspects According to the Present Disclosure

As can be seen from the abovementioned embodiments, a lens unit 10 according to a first aspect of the disclosure includes a plurality of lens cores it and a main body 2. The plurality of lens cores it is configured to be provided one-to-one in front of a plurality of LEDs 21 with different luminous colors. The main body 2 holds the plurality of lens cores 1t. The plurality of lens cores it is held by the main body 2 so that respective distances of the plurality of lens cores it from respective light-emitting surfaces 21aa of LED chips 21a in the plurality of LEDs 21 are equal to each other. In an example, the LED chips 21a in the plurality of LEDs 21 include at least one first LED chip 21s and at least one second LED chip 21t. The first LED chip 21s and the second LED chip 21t respectively have a first height H1 and a second height H2 that are different from each other. The first height H1 is a distance between a lower surface (corresponding to the mounting surface 22aa) of the base substance 21b in the first LED chip 21s and the light-emitting surface 21aa of the luminous layer 21g in the first LED chip 21s. The second height H2 is a distance between a lower surface (corresponding to the mounting surface 22aa) of the base substance 21b in the second LED chip 21t and the light-emitting surface 21aa of the luminous layer 21g in the second LED chip 21t.

With the lens unit 10 according to the first aspect, since the plurality of lens cores it is held by the main body 2 so that the respective distances of the plurality of lens cores it from the respective light-emitting surfaces 21aa of the LED chips 21a are equal to each other, it is possible to radiate light with color irregularity thereof more reduced on a radiation surface.

In a lens unit 10 according to a second aspect of the disclosure, each of the plurality of lens cores it has a light entrance surface 1aa, a light exit surface ice, and a thickness between the light entrance surface 1aa and the light exit surface ice. The thicknesses of the plurality of lens cores it are equal to each other.

In the lens unit 10 according to the second aspect, since the thicknesses of the plurality of lens cores it are equal to each other, luminous intensity distribution can be controlled by a comparatively simple configuration.

An LED module 20 according to a third aspect of the present disclosure includes a mounting substrate 22, a plurality of LEDs 21 and a lens unit 10. The mounting substrate 22 includes a mounting surface 22aa. The plurality of LEDs 21 includes at least first and second LEDs 21m, 21n that are mounted on the mounting surface 22aa and configured to radiate different luminous colors of light. The first and second LEDs 21m, 21n respectively include first and second LED chips 21s, 21t, each of which includes a luminous layer 21g with a light-emitting surface 21aa. The light-emitting surfaces 21aa of the first and second LED chips 21s, 21t have different heights H1, H2 from the mounting surface 22aa, respectively. The lens unit 10 includes a plurality of lens cores it including at least first and second lens cores 1m, in, and a main body 2 holding the plurality of lens cores it. The lens unit 10 is provided to cover the mounting substrate 22 with the first and second lens cores 1m, 1n respectively disposed in front of the first and second LEDs 21m, 21n. The first and second lens cores 1m, 1n have first and second distances L1, L2, respectively. The first and second distances L1, L2 are distances from the light-emitting surfaces 21aa of the first and second LEDs 21m, 21n to the first and second lens cores 1m, in, respectively. The first and second lens cores 1m, 1n also have first and second intervals D1, D2, respectively. The first and second intervals D1, D2 are intervals from the mounting surface 22aa to the first and second lens cores 1m, in, respectively. A difference between the first and second distances L1, L2 is smaller than a difference between the first and second intervals D1, D2.

The LED module 20 according to the third aspect can have a configuration having the lens unit 10 capable of radiating light with color irregularity thereof more reduced on a radiation surface.

In the third aspect, each of the first and second lens cores 1m, 1n of an LED module 20 according to a fourth aspect of the present disclosure has a light entrance surface 1aa, a light exit surface ice, and a thickness between the light entrance surface 1aa and the light exit surface ice. The thicknesses of the first and second lens cores 1m, 1n are equal to each other. The first and second LEDs 21m, 21n further include convex lenses covering the first and second LED chips 21s, 21t, respectively. External shapes of the convex lenses of the first and second LEDs 21m, 21n are equal to each other.

With the LED module 20 according to the fourth aspect, luminous intensity distribution can be controlled by a comparatively simple configuration.

In the third and fourth aspects, a light fixture 30 according to a fifth aspect of the present disclosure includes the LED module 20 and a fixture body 31. The fixture body 31 holds the LED module 20.

The light fixture 30 according to the fifth aspect can have a configuration having the LED module 20 capable of radiating light with color irregularity thereof more reduced on a radiation surface.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A lens unit, comprising:
lens cores configured to be provided one-to-one in front of LEDs with different luminous colors;
a main body that holds the lens cores, wherein respective distances of the lens cores from respective light-emitting surfaces of LED chips in the LEDs are equal to each other.

2. The lens unit of claim 1, wherein:
each of the lens cores has a light entrance surface, a light exit surface, and a thickness between the light entrance surface and the light exit surface; and
the thicknesses of the lens cores are equal to each other.

3. An LED module, comprising:
a mounting substrate including a mounting surface;
LEDs including at least first and second LEDs that are mounted on the mounting surface and configured to radiate different luminous colors of light, the first and second LEDs respectively comprising first and second LED chips, each of which includes a luminous layer with a light-emitting surface, the light-emitting surfaces of the first and second LED chips having different first and second heights from the mounting surface, respectively; and
a lens unit that comprises lens cores including at least first and second lens cores, and a main body holding the lens cores, the lens unit being provided to cover the mounting substrate with the first and second lens cores respectively disposed in front of the first and second LEDs,
the first and second lens cores having first and second distances, respectively, the first and second distances being distances from the light-emitting surfaces of the first and second LEDs to the first and second lens cores, respectively, the first and second lens cores also having first and second intervals, respectively, the first and second intervals being intervals from the mounting surface to the first and second lens cores, respectively, a difference between the first and second distances being smaller than a difference between the first and second intervals.

4. The LED module of claim 3, wherein:
each of the first and second lens cores has a light entrance surface, a light exit surface, and a thickness between the light entrance surface and the light exit surface;
the thicknesses of the first and second lens cores are equal to each other;
the first and second LEDs further comprise convex lenses covering the first and second LED chips, respectively; and
external shapes of the convex lenses of the first and second LEDs are equal to each other.

5. The LED module of claim 3, wherein the main body holds the lens cores so that the first and second intervals are different from each other.

6. The LED module of claim 4, wherein the main body holds the lens cores so that the first and second intervals are different from each other.

7. The LED module of claim 3, wherein the first and second distances are equal to each other.

8. The LED module of claim 4, wherein the first and second distances are equal to each other.

9. The LED module of claim 5, wherein the first and second distances are equal to each other.

10. The LED module of claim 6, wherein the first and second distances are equal to each other.

11. A light fixture, comprising:
an LED module of claim 3; and
a fixture body that holds the LED module.

12. A light fixture, comprising:
an LED module of claim 4; and
a fixture body that holds the LED module.

13. A light fixture, comprising:
an LED module of claim 5; and
a fixture body that holds the LED module.

14. A light fixture, comprising:
an LED module of claim 6; and
a fixture body that holds the LED module.

15. A light fixture, comprising:
an LED module of claim 7; and
a fixture body that holds the LED module.

16. A light fixture, comprising:
an LED module of claim 8; and
a fixture body that holds the LED module.

17. A light fixture, comprising:
an LED module of claim 9; and
a fixture body that holds the LED module.

18. A light fixture, comprising:
an LED module of claim 10; and
a fixture body that holds the LED module.
